(19) United States
(12) Patent Application Publication
(10) Pub. No.: US 2006/0083279 A1
(43) Pub. Date: Apr. 20, 2006

(54) Semiconductor laser

(75) Inventors: Tatsuya Kimura, Tokyo (JP); Kenichi Ono, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 11/142,438

(22) Filed: Jun. 2, 2005

(30) Foreign Application Priority Data
Oct. 19, 2004 (JP) 2004-303750

(51) Int. Cl. H01S 5/00

(52) U.S. Cl. 372/43.01

(57) ABSTRACT

A semiconductor laser in which six layers are grown on one another, over an Si—GaAs substrate, in the following order: an Si—GaAs buffer layer, an Si—AlGaInP cladding layer, an active layer, an Mg—AlGaInP cladding layer, an Mg—AlGaInP band discontinuity reduction layer, and a Zn—GaAs contact layer. In this configuration, the carrier concentration of the Si—GaAs substrate may be from 1×10¹⁷ cm⁻³ to 7×10¹⁷ cm⁻³ to reduce the number of atoms diffusing from the Si—GaAs substrate into the active layer and so the active layer of the semiconductor laser has good light emission characteristics.

### BACKGROUND OF THE INVENTION

1. Field of the Invention

The present invention relates to a semiconductor laser, and more particularly to a semiconductor laser using a GaAs substrate.

2. Background Art

Various semiconductor lasers using a GaAs substrate have been proposed (see, e.g., Japanese Patent Laid-Open Nos. 7-193331, 2002-33553, and 2001-237496).

For example, an AlGaInP semiconductor laser is configured such that six layers are grown onto one another over an Si—GaAs substrate in the following order: an Si—GaAs buffer layer; an Si—AlGaInP lower cladding layer; an active layer including an AlGaInP/GaInP multiple quantum well (MQW) structure; an Mg—AlGaInP upper cladding layer; an Mg—AlGaInP band discontinuity reduction layer; and a Zn—GaAs contact layer. In such a configuration, efficiently injecting a current into the active layer causes red laser light to be emitted from an end face of the active layer.

However, the substrate of conventional semiconductor lasers contains large quantities of Ga and As atoms and impurities in the interstitial sites of GaAs crystal. Therefore, these atoms and impurities diffuse from the Si—GaAs substrate into the active layer and thereby degrade the layer, resulting in degradation in the characteristics of the semiconductor laser.

### SUMMARY OF THE INVENTION

The present invention has been devised in view of the above problem. It is, therefore, an object of the present invention to provide a semiconductor laser in which a reduced number of atoms diffuse from the GaAs substrate into the active layer, which allows the semiconductor laser to have enhanced characteristics.

According to one aspect of the present invention, a semiconductor laser comprises a GaAs substrate of a first conductive type, and a grown structure formed over the GaAs substrate, the grown structure including a cladding layer of the first conductive type, an active layer, and a cladding layer of a second conductive type. The cladding layer of the first conductive type, the active layer, and the cladding layer of the second conductive type are made of AlGaInP-based material. The GaAs substrate has a carrier concentration between 1×10¹⁷ cm⁻³ and 7×10¹⁷ cm⁻³, inclusive.

According to another aspect of the present invention, a semiconductor laser comprises a GaAs substrate of a first conductive type, and a grown structure formed over the GaAs substrate, the grown structure including a cladding layer of the first conductive type, an active layer, and a cladding layer of a second conductive type. The cladding layer of the first conductive type, the active layer, and the cladding layer of the second conductive type are made of AlGaAs-based material. The GaAs substrate has a carrier concentration between 1×10¹⁷ cm⁻³ and 7×10¹⁷ cm⁻³, inclusive.

According to other aspect of the present invention, a semiconductor laser comprises a GaAs substrate of a first conductive type; a first grown structure formed over the GaAs substrate, the first grown structure including a cladding layer of the first conductive type, an active layer, and a cladding layer of a second conductive type which are made of AlGaInP-based material; and a second grown structure formed over the GaAs substrate, the second grown structure including a cladding layer of the first conductive type, an active layer, and a cladding layer of the second conductive type which are made of AlGaAs-based material. The GaAs substrate has a carrier concentration between 1×10¹⁷ cm⁻³ and 7×10¹⁷ cm⁻³, inclusive.

Other objects and advantages of the present invention will become apparent from the following description.

### BRIEF DESCRIPTION OF THE DRAWINGS

FIG. 1 is a diagram showing the configuration of a semiconductor laser according to a first embodiment.

FIGS. 2A to 2D are cross-sectional views illustrating a method for manufacturing a semiconductor laser according to a first embodiment.

FIG. 3 shows the relationship between the carrier concentration of the substrate and the operating current of the semiconductor laser according to a first embodiment.

FIG. 4 shows the relationship between the carrier concentration and the Si atom concentration of the substrate according to a first embodiment.

FIG. 5 shows the relationship between the carrier concentration and the resistance of the substrate according to a first embodiment.

FIG. 6 is a diagram showing the configuration of a semiconductor laser according to a second embodiment.

FIGS. 7A to 7C are cross-sectional views illustrating a method for manufacturing a semiconductor laser according to a second embodiment.

FIG. 8 is a diagram showing the configuration of a semiconductor laser according to a third embodiment.

FIGS. 9A to 9C are cross-sectional views illustrating a method for manufacturing a semiconductor laser according to a third embodiment.

FIG. 10 shows the relationship between the carrier concentration of the substrate and the operating current of the semiconductor laser according to a third embodiment.

FIG. 11 is a diagram showing the configuration of a semiconductor laser according to a fourth embodiment.

### DETAILED DESCRIPTION OF THE PREFERRED EMBODIMENTS

Conventional semiconductor lasers have employed an Si—GaAs substrate having a carrier concentration higher than 7×10¹⁷ cm⁻³. However, after intensive study, the present inventor has found that the carrier concentration of the Si—GaAs substrate may be reduced to less than conventional values (that is, to 7×10¹⁷ cm⁻³ or less) to provide a semiconductor laser having enhanced characteristics. Preferred embodiments of the present invention will be described below with the accompanying drawings.

### First Embodiment

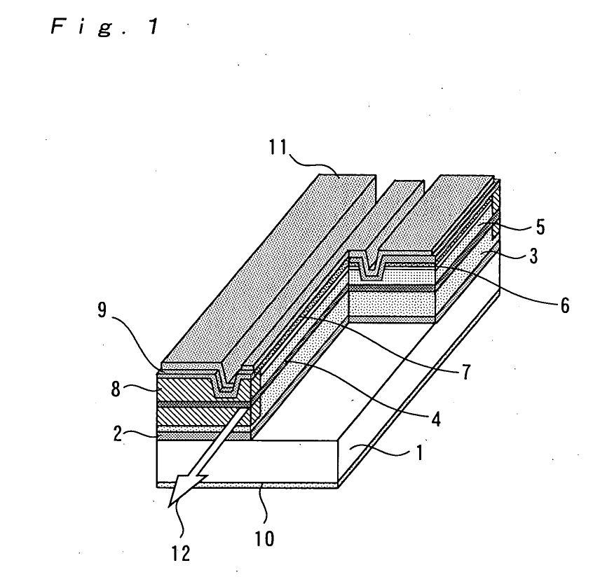

FIG. 1 is a diagram showing the configuration of a semiconductor laser according to a first embodiment of the present invention.

Referring to the figure, an Si—GaAs substrate 1 (that is, a GaAs substrate of a first conductive type) may be a 3-inch substrate having a substrate surface tilt angle (or an off-angle) of 10 degrees with respect to the (100) crystal plane, for example.

Further, according to the present invention, the carrier concentration of the Si—GaAs substrate 1 is set between 1×10¹⁷ cm⁻³ and 7×10¹⁷ cm⁻³, inclusive. That is, the present invention is characterized in that the carrier concentration of the substrate is set to less than conventional values (that is, to 7×10¹⁷ cm⁻³ or less).

According to the present embodiment, a ridge type AlGaInP semiconductor laser is formed on an Si—GaAs substrate.

Referring to FIG. 1, six layers are grown onto one another over the Si—GaAs substrate 1 in the following order: an Si—GaAs buffer layer 2; an Si—AlGaInP cladding layer 3 (a cladding layer of a first conductive type); an active layer 4 including an AlGaInP/GaInP multiple quantum well (MQW) structure; an Mg—AlGaInP cladding layer 5 (a cladding layer of a second conductive type); an Mg—AlGaInP band discontinuity reduction (hereinafter abbreviated as “BDR”) layer 6; and a Zn—GaAs contact layer 7. In the figure, reference numeral 8 denotes a Zn diffusion window layer; 9 denotes an SiN insulating film; 10 denotes an n-type electrode; and 11 denotes a p-type electrode.

The Si—GaAs buffer layer 2 may have a carrier concentration of approximately 5×10¹⁷ cm⁻³ and a film thickness of approximately 0.5 μm, for example.

The Si—AlGaInP cladding layer 3 may have a carrier concentration of approximately 5×10¹⁷ cm⁻³ and a film thickness of approximately 2.5 μm, for example. The composition ratio of the cladding layer is adjusted such that its energy is equivalent to a wavelength of approximately 530 nm.

The composition ratio of the active layer 4 is adjusted such that its energy is equivalent to a wavelength of approximately 660 nm.

The Mg—AlGaInP cladding layer 5 may have a carrier concentration of approximately 1×10¹⁸ cm⁻³ and a film thickness of approximately 2.5 μm, for example. Further, the composition ratio of this cladding layer is adjusted such that its energy is equivalent to a wavelength of approximately 530 nm.

The Mg—AlGaInP BDR layer 6 may have a carrier concentration of approximately 1×10¹⁸ cm⁻³ and a film thickness of approximately 0.1 μm, for example. Further, the composition ratio of the BDR layer is adjusted such that its energy is equivalent to a wavelength of approximately 650 nm.

The Zn—GaAs contact layer 7 may have a carrier concentration of approximately 1×10¹⁹ cm⁻³ and a film thickness of approximately 0.5 μm, for example.

In such a configuration, efficiently injecting a current into the active layer 4 causes red laser light 12 to be emitted from an end face of the active layer 4. It should be noted that the Zn diffusion window layer 8 functions to prevent the end face from being degraded by the laser light 12.

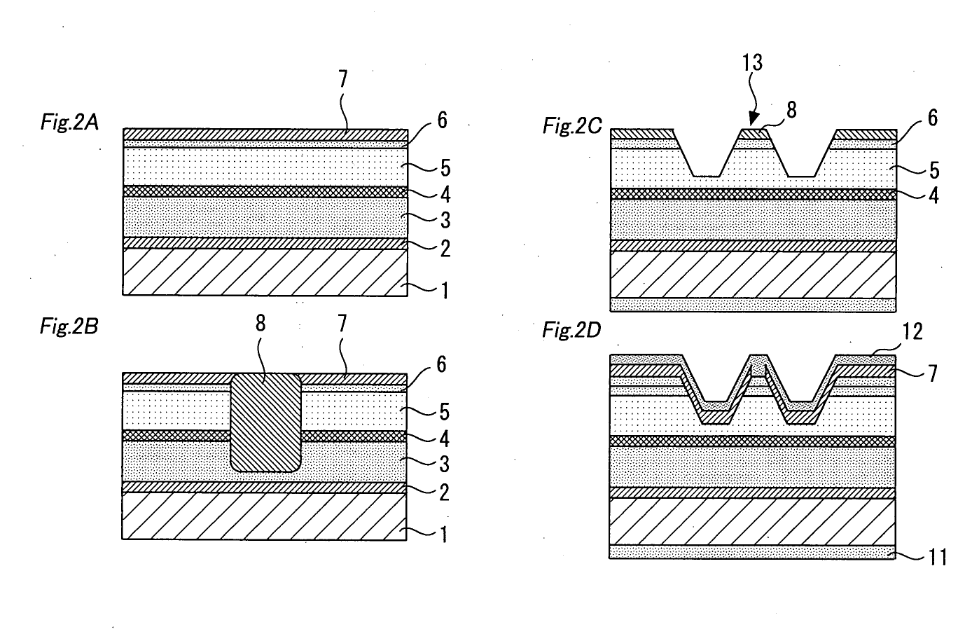

A description will be given below of a method for manufacturing the semiconductor laser shown in FIG. 1 with reference to FIGS. 2A to 2D. It should be noted that components in these figures which are the same as those in FIG. 1 are denoted by like numerals.

First of all, as shown in FIG. 2A, six layers are “crystal-grown” over the the Si—GaAs substrate 1 by the metalorganic chemical vapor deposition. (MOCVD) technique in the following order: the Si—GaAs buffer layer 2, the Si—AlGaInP cladding layer 3, the active layer 4, the Mg—AlGaInP cladding layer 5, the Mg—AlGaInP BDR layer 6, and the Zn—GaAs contact layer 7.

Then, Zn is diffused into the region which will become an end face of the active layer 4, forming the Zn diffusion window layer 8, as shown in FIG. 2B.

Then, a pattern (not shown) is formed by a photolithographic technique; the pattern has openings on both sides of the region that will become an optical waveguide 13. Then, etching is carried out through these openings until a position approximately 0.5 μm high from the top surface of the active layer 4 is reached, as shown in FIG. 2C.

Then, after forming the SiN insulating film 9 on the entire top surface, the portion of the SiN insulating film 9 (on the Zn—GaAs contact layer 7) above the top of the ridge-shaped optical waveguide portion 13 is removed. After that, the n-type electrode 10 is formed on the back surface and the p-type electrode 11 is formed on the top surface, as shown in FIG. 2D. Then, both end faces of the semiconductor laser are formed through cleavage, and an antireflective film (not shown) is formed on these end faces, producing the structure shown in FIG. 1.

According to the present invention, the carrier concentration of the Si—GaAs substrate is set to less than conventional values (which are between 7×10¹⁷ cm⁻³ and 2.5×10¹⁸ cm⁻³, for example). This can reduce the numbers of Ga and As atoms and Si atoms (acting as impurities) which are present in the interstitial sites of GaAs crystal.

The atoms that have diffused from the Si—GaAs substrate to the active layer usually become defects, thereby degrading the light emission characteristics within the crystal. However, since the present invention reduces the concentration of the interstitial Ga, As, and Si atoms, a reduced number of atoms diffuse from the Si—GaAs substrate to the active layer (as compared to conventional arrangements). Therefore, it is possible to prevent degradation of the light emission characteristics of the active layer, allowing the semiconductor laser to have enhanced characteristics.

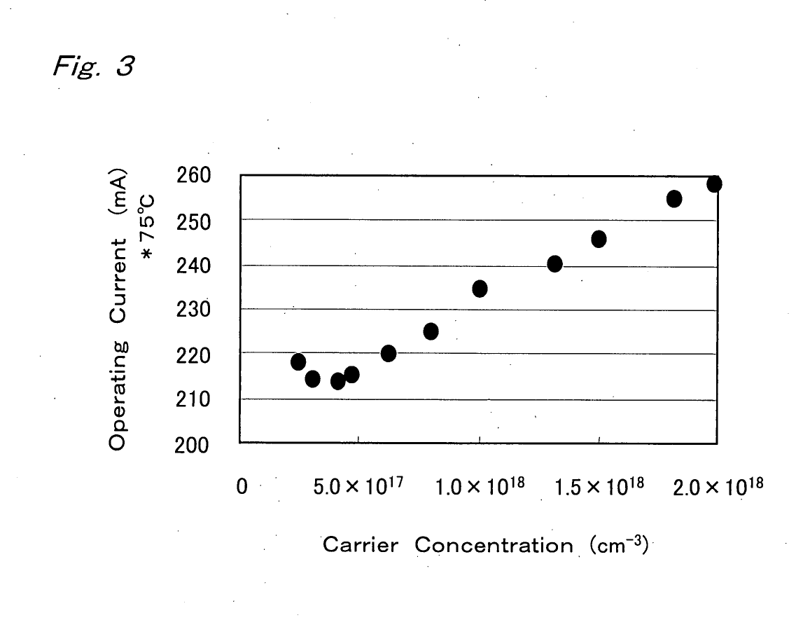

FIG. 3 shows the relationship between the carrier concentration of the substrate and the operating current of the semiconductor laser. The figure indicates that the operating current decreases with decreasing carrier concentration of the substrate.

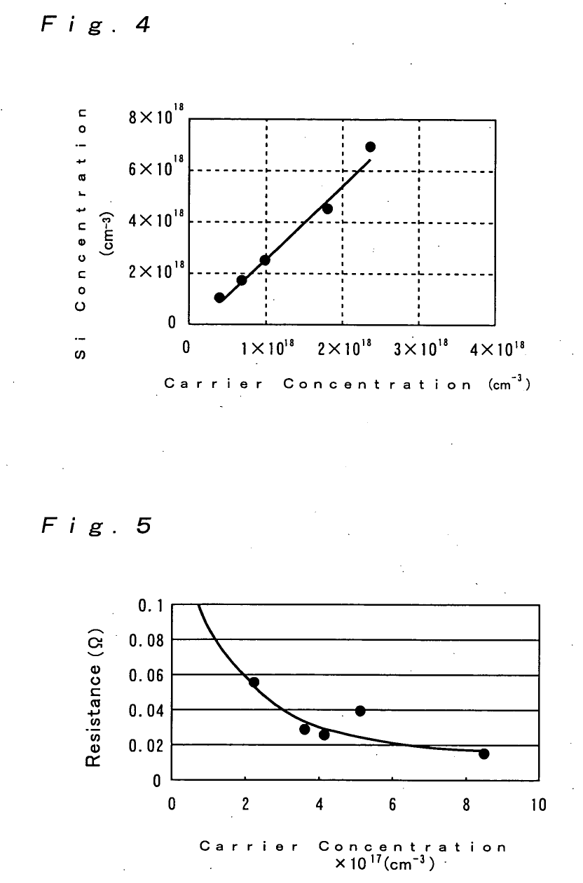

FIG. 4 shows the relationship between the carrier concentration and the Si atom concentration of the substrate. The figure indicates that the Si atom concentration decreases with decreasing carrier concentration. It should be noted that the activation ratio of Si atoms is approximately 40%. This means that the substrate contains a concentration of inactive Si atoms equal to or higher than the carrier concentration. Further, the number of Ga and As atoms present in the interstitial sites is related to the number of inactive Si atoms; the concentration of Ga and As atoms decreases with decreasing concentration of inactive Si atoms. Therefore, the carrier concentration in the substrate may be reduced to reduce the concentration of inactive Si atoms and hence the concentration of Ga and As atoms present in the interstitial sites. This explains the results shown in FIG. 3.

It should be noted that high power semiconductor lasers must be formed such that their operating current is low at high temperatures. Specifically, the operating current is preferably 220 mA or less at 75° C. Based on this requirement and the results in FIG. 3, the present invention sets the carrier concentration of the substrate to 7×10¹⁷ cm⁻³ or less.

On the other hand, a reduction in the carrier concentration of the substrate results in an increase in the resistance between the substrate and the n-type electrode, as shown in FIG. 5. This leads to an increase in the device resistance of the semiconductor laser and hence an increase in its operating voltage. Further, reducing the carrier concentration of the substrate might increase the number of dislocations within the substrate and thereby reduce the reliability of the semiconductor laser. Still further, the so-called undoped GaAs substrate, in which Si atoms are not deliberately doped, usually contains a carrier concentration on the order of 10¹⁶ cm⁻³. This means that it is difficult to adjust the carrier concentration of an Si—GaAs substrate to any given value less than 1×10¹⁷ cm⁻³. In this respect, the present invention sets the carrier concentration of the substrate to 1×10¹⁷ cm⁻³ or more.

In view of the above considerations, the present invention sets the carrier concentration of the Si—GaAs substrate to between 1×10¹⁷ cm⁻³ and 7×10¹⁷ cm⁻³, inclusive. Particularly, the carrier concentration of the substrate is preferably between 3×10¹⁷ cm⁻³ and 5×10¹⁷ cm⁻³, inclusive. This can reduce the number of atoms diffusing from the Si—GaAs substrate into the active layer and thereby allow the active layer of the semiconductor laser to have good light emission characteristics.

### Second Embodiment

A second embodiment of the present invention is different from the first embodiment in that a buried ridge type AlGaInP semiconductor laser is formed on an Si—GaAs substrate, instead of an ordinary ridge type AlGaInP semiconductor laser.

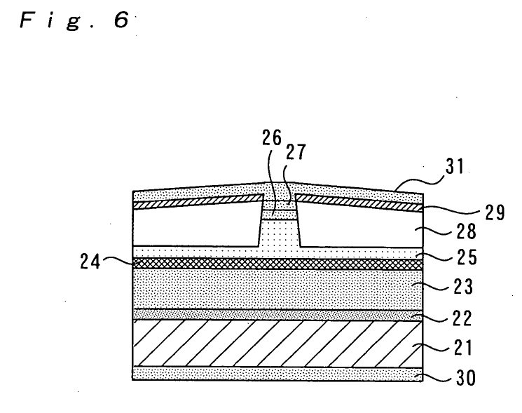

FIG. 6 is a diagram showing the configuration of a semiconductor laser according to the present embodiment.

Referring to the figure, reference numeral 21 denotes an Si—GaAs substrate (that is, a GaAs substrate of a first conductive type). The Si—GaAs substrate 21 may be a 3-inch substrate having a substrate surface tilt angle (or an off-angle) of 10 degrees with respect to the (100) crystal plane.

Further, the carrier concentration of the Si—GaAs substrate 21 is set between 1×10¹⁷ cm⁻³ and 7×10¹⁷ cm⁻³, inclusive. That is, like the first embodiment, the present embodiment is characterized in that the carrier concentration of the Si—GaAs substrate is set to 7×10¹⁷ cm⁻³ or less (that is, less than conventional values).

As described above, according to the present embodiment, a buried ridge type AlGaInP semiconductor laser is formed on an Si—GaAs substrate.

Referring to FIG. 6, six layers are grown onto one another over the Si—GaAs substrate 21 in the following order: an Si—GaAs buffer layer 22; an Si—AlGaInP cladding layer 23 (a cladding layer of a first conductive type); an active layer 24 including an AlGaInP/GaInP multiple quantum well (MQW) structure; an Mg—AlGaInP cladding layer 25 (a cladding layer of a second conductive type); an Mg—AlGaInP band discontinuity reduction (hereinafter abbreviated as “BDR”) layer 26; and a Zn—GaAs contact layer 27. In the figure, reference numeral 28 denotes an Si—AlInP current blocking layer; 29 denotes an SiN insulating film; 30 denotes an n-type electrode; and 31 denotes a p-type electrode.

The Si—GaAs buffer layer 22 may have a carrier concentration of approximately 5×10¹⁷ cm⁻³ and a film thickness of approximately 0.5 μm, for example.

The Si—AlGaInP cladding layer 23 may have a carrier concentration of approximately 5×10¹⁷ cm⁻³ and a film thickness of approximately 2.5 μm, for example. Further, the composition ratio of this cladding layer is adjusted such that its energy is equivalent to a wavelength of approximately 530 nm.

The composition ratio of the active layer 24 is adjusted such that its energy is equivalent to a wavelength of approximately 660 nm.

The Mg—AlGaInP cladding layer 25 may have a carrier concentration of approximately 1×10¹⁸ cm⁻³ and a film thickness of approximately 2.5 μm, for example. Further, the composition ratio of this cladding layer is adjusted such that its energy is equivalent to a wavelength of approximately 530 nm.

The Mg—AlGaInP BDR layer 26 may have a carrier concentration of approximately 1×10¹⁸ cm⁻³ and a film thickness of approximately 0.1 μm, for example. Further, the composition ratio of the BDR layer is adjusted such that its energy is equivalent to a wavelength of approximately 560 nm.

The Zn—GaAs contact layer 27 may have a carrier concentration of approximately 1×10¹⁹ cm⁻³ and a film thickness of approximately 0.5 μm, for example.

The Si—AlInP current blocking layer 28 may have a carrier concentration of approximately 5×10¹⁷ cm⁻³ and a film thickness of approximately 0.5 μm, for example.

The Si—AlInP current blocking layer 28 allows a current to be efficiently injected into the active layer 24, thereby causing red laser light (not shown) to be emitted from an end face of the active layer 24. That is, the Si—AlInP current blocking layer 28 functions to constrict the current flowing in the active layer 24. Further, as shown in FIG. 6, the Si—AlInP current blocking layer 28 is provided on the Mg—AlGaInP cladding layer 25 such that materials having different refractive indices (that is, AlInP and AlGaInP) are formed laterally adjacent each other on the active layer 24. Such an arrangement produces the effect of confining the light.

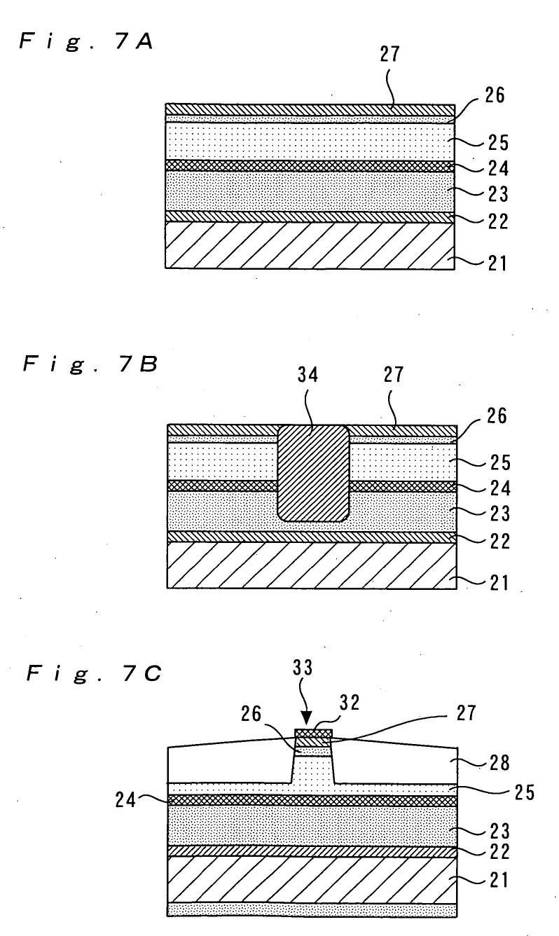

A description will be given below of a method for manufacturing the semiconductor laser shown in FIG. 6 with reference to FIGS. 7A to 7C. It should be noted that components in these figure which are the same as those in FIG. 6 are denoted by like numerals.

First of all, as shown in FIG. 7A, six layers are “crystal grown” over the Si—GaAs substrate 21 by the metalorganic chemical vapor deposition (MOCVD) technique in the following order: the Si—GaAs buffer layer 22, the Si—AlGaInP cladding layer 23, the active layer 24, the Mg—AlGaInP cladding layer 25, the Mg—AlGaInP BDR layer 26, and the Zn—GaAs contact layer 27.

Then, Zn is diffused into the region which will become an end face of the active layer 24, forming the Zn diffusion window layer 34, as shown in FIG. 7B.

Then, after forming an SiN insulating film 32 on the entire top surface, portions of the SiN insulating film 32 other than that on the region that will become an optical waveguide 33 are removed by a photolithographic technique, thus processing the SiN insulating film 32 into a stripe shape having a width of approximately 1 μm.

Then, the Zn—GaAs contact layer 27, the Mg—AlGaInP BDR layer 26, and the Mg—AlGaInP cladding layer 25 are etched. This etching is stopped when the Mg—AlGaInP cladding layer 25 has been etched to a depth of 2 μm, thus forming the ridge-shaped waveguide 33.

After that, the Si—AlInP current blocking layer 28 is formed by the MOCVD technique. At that time, the Si—AlInP current blocking layer 28 is selectively “crystal-grown” on the Mg—AlGaInP cladding layer 25, not on the SiN insulating film 32, as shown in FIG. 7C.

Then, after removing the SiN insulating film 32, the SiN insulating film 29 is formed on the entire top surface. Then, the portion of the SiN insulating film 29 (on the Zn—GaAs contact layer 27) above the top of the optical waveguide portion 33 is removed. After that, the n-type electrode 31 is formed on the back surface and the p-type electrode 30 is formed on the top surface. Then, both end faces of the semiconductor laser are formed through cleavage, and antireflective film (not shown) is formed on these end faces, producing the structure shown in FIG. 6.

According to the present embodiment, the carrier concentration of the Si—GaAs substrate is set between 1×10¹⁷ cm⁻³ and 7×10¹⁷ cm⁻³, inclusive, as in the case of the first embodiment. Particularly, the carrier concentration of the substrate is preferably between 3×10¹⁷ cm⁻³ and 5×10¹⁷ cm⁻³, inclusive. This can reduce the number of atoms diffusing from the Si—GaAs substrate into the active layer and thereby allow the active layer of the semiconductor layer to have good light emission characteristics.

The relationship between the carrier concentration of the substrate and the operating current of the semiconductor laser according to the present embodiment is similar to that for the first embodiment shown in FIG. 3. However, the actual operating current value is larger than that of the first embodiment over the entire range of carrier concentration. The reason for this is that the present embodiment causes a larger number of atoms to diffuse from the substrate than the first embodiment, since the present embodiment performs crystal growth twice whereas the first embodiment performs it only once.

### Third Embodiment

A third embodiment of the present invention is different from the first embodiment in that a ridge type AlGaAs semiconductor laser is formed on an Si—GaAs substrate, instead of a ridge type AlGaInP semiconductor laser.

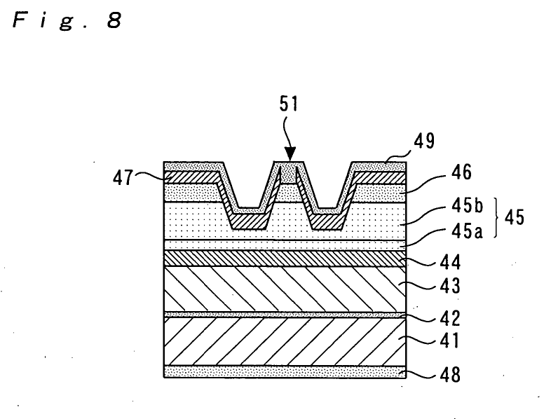

FIG. 8 is a diagram showing the configuration of a semiconductor laser according to the present embodiment.

Referring to the figure, reference numeral 41 denotes an Si—GaAs substrate (that is, a GaAs substrate of a first conductive type). The Si—GaAs substrate 41 may be, for example, a (100) substrate (or a “just substrate”).

Further, the carrier concentration of the Si—GaAs substrate 41 is set between 1×10¹⁷ cm⁻³ and 7×10¹⁷ cm⁻³, inclusive. That is, like the first embodiment, the present embodiment is characterized in that the carrier concentration of the Si—GaAs substrate is set to 7×10¹⁷ cm⁻³ or less (that is, less than conventional values).

As described above, according to the present embodiment, a ridge type AlGaAs semiconductor laser is formed on an Si—GaAs substrate.

Referring to FIG. 8, five layers are grown onto one another over the Si—GaAs substrate 41 in the following order: an Si—GaAs buffer layer 42; an Si—AlGaAs cladding layer 43 (a cladding layer of a first conductive type); an active layer 44 including an AlGaAs/AlGaAs multiple quantum well (MQW) structure; a Zn—AlGaAs cladding layer 45 (a cladding layer of a second conductive type); and a Zn—GaAs contact layer 46. In the figure, reference 47 denotes an SiN insulating film; 48 denotes an n-type electrode; and 49 denotes a p-type electrode.

The Si—GaAs buffer layer 42 may have a carrier concentration of approximately 5×10¹⁷ cm⁻³ and a film thickness of approximately 0.5 μn, for example.

The Si—AlGaAs cladding layer 43 may have a carrier concentration of approximately 5×10¹⁷ cm⁻³ and a film thickness of approximately 2.5 μn, for example. Further, the composition ratio of this cladding layer is adjusted such that its energy is equivalent to a wavelength of approximately 610 nm.

The composition ratio of the active layer 44 is adjusted such that its energy is equivalent to a wavelength of approximately 780 nm.

The Zn—AlGaAs cladding layer 45 may have a carrier concentration of approximately 1×10¹⁸ cm⁻³, for example. Further, the composition ratio of this cladding layer is adjusted such that its energy is equivalent to a wavelength of approximately 610 nm.

The Zn—GaAs contact layer 46 may have a carrier concentration of approximately 1×10¹⁹ cm⁻³ and a film thickness of approximately 0.5 μm, for example.

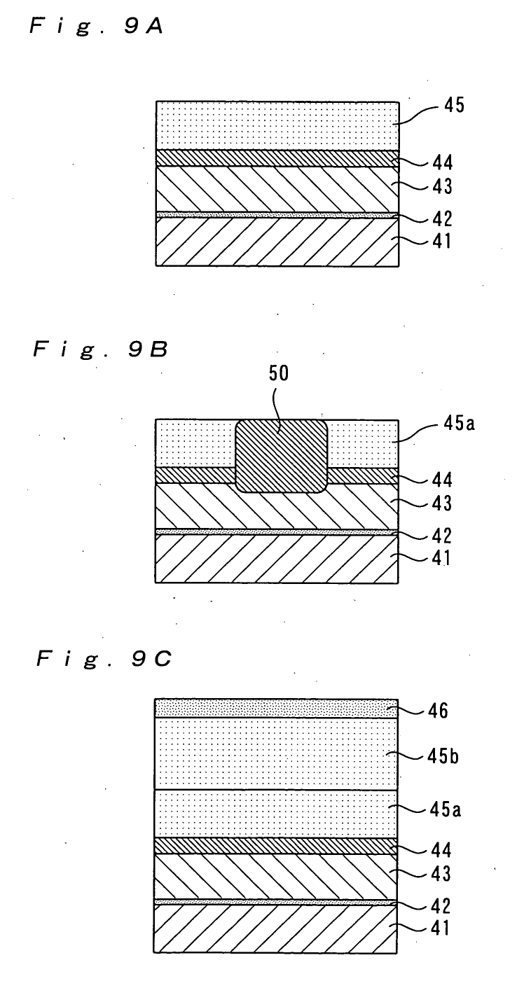

A description will be given below of a method for manufacturing the semiconductor laser shown in FIG. 8 with reference to FIGS. 9A to 9C. It should be noted that components in these figures which are the same as those in FIG. 8 are denoted by like numerals.

First of all, as shown in FIG. 9A, four layers are “crystal grown” over the Si—GaAs substrate 41 by the metalorganic chemical vapor deposition (MOCVD) technique in the following order: the Si—GaAs buffer layer 42, the Si—AlGaAs cladding layer 43, the active layer 44, and a first Zn—AlGaAs cladding layer 45a. The first Zn—AlGaAs cladding layer 45a has a film thickness of approximately 0.4 μm.

Then, Si is diffused into the region which will become an end face of the active layer 44, forming the Si diffusion window layer 50, as shown in FIG. 9B. It should be noted that since the Si diffusion window layer 50 is formed only on an end face portion of the semiconductor layer, it is not shown in FIGS. 8 and 9A and 9C.

Then, a second Zn—AlGaAs cladding layer 45b and the Zn—GaAs contact layer 46 are formed over the first Zn—AlGaAs cladding layer 45a by the MOCVD technique in that order, as shown in FIG. 9C. The second Zn—AlGaAs cladding layer 45b has a film thickness of approximately 2.0 μm.

Then, a pattern (not shown) is formed by a photolithographic technique; the pattern has openings on both sides of the region that will become an optical waveguide 51. Then, etching is carried out through these openings until a position 0.5 μm high from the top surface of the active layer 44 is reached. This removes most of the portions of the second Zn—AlGaAs cladding layer 45b exposed at the openings. However, no portion of the first Zn—AlGaAs cladding layer 45a is etched. The remaining portion of the second Zn—AlGaAs cladding layer 45b and the first Zn—AlGaAs cladding layer 45a constitute the Zn—AlGaAs cladding layer 45 shown in FIG. 8.

Then, after forming the SiN insulating film 47 on the entire top surface, the portion of the SiN insulating film 47 (on the Zn—GaAs contact layer 46) above the top of the ridge-shaped optical waveguide portion 51 is removed. After that, the n-type electrode 48 is formed on the back surface and the p-type electrode 49 is formed on the top surface. Then, both end faces of the semiconductor laser are formed through cleavage, and an antireflective film (not shown) is formed on these end faces, producing the structure shown in FIG. 8.

According to the present embodiment, the carrier concentration of the Si—GaAs substrate is set between 1×10¹⁷ cm⁻³ and 7×10¹⁷ cm⁻³, inclusive, as in the case of the first embodiment. Particularly, the carrier concentration of the substrate is preferably between 5×10¹⁷ cm⁻³ and 6×10¹⁷ cm⁻³, inclusive. This can reduce the number of atoms diffusing from the Si—GaAs substrate into the active layer and thereby allow the active layer of the semiconductor laser to have good light emission characteristics.

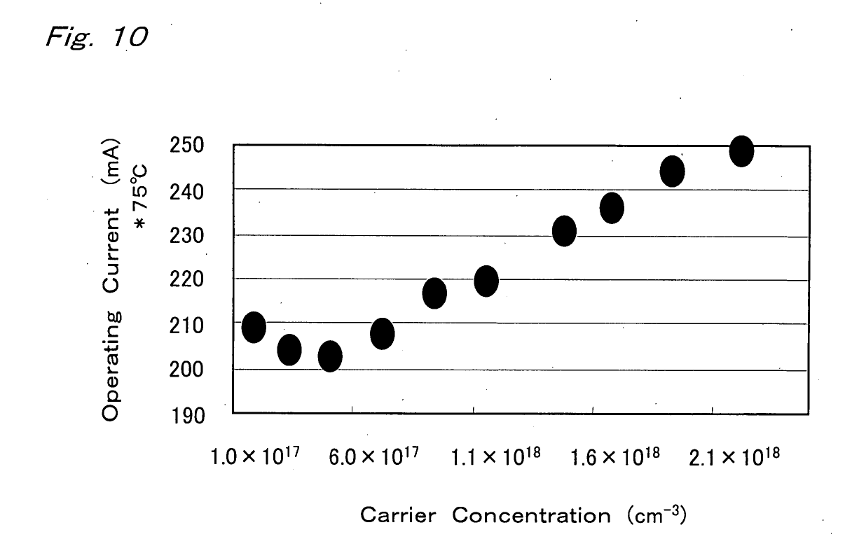

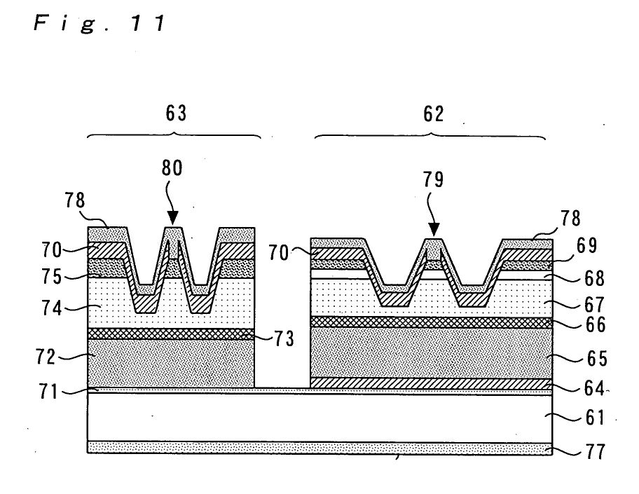

FIG. 10 shows the relationship between the carrier concentration of the substrate and the operating current of the semiconductor laser according to the present embodiment. As shown in the figure, the operating current is minimized at a substrate carrier concentration approximately between 5×10¹⁷ cm⁻³ and 6×10¹⁷ cm⁻³ and then increases with increasing carrier concentration. It should be noted that the operating current of an AlGaInP semiconductor laser (such as that of the first embodiment) is minimized at a lower substrate carrier concentration than the operating current of an AlGaAs semiconductor laser, as shown in FIG. 3. The reason for this will be described below.

As described in connection with the first embodiment, the Si atom concentration decreases with decreasing substrate carrier concentration, as shown in FIG. 4. It should be noted that the activation ratio of Si atoms is approximately 40%. This means that the substrate contains a concentration of inactive Si atoms equal to or higher than the carrier concentration. As can be seen from the figure, the carrier concentration of the substrate may be reduced to reduce the concentration of inactive Si atoms and hence the concentration of Ga and As atoms present in the interstitial sites. On the other hand, Ga, As, and Si atoms diffuse at a few times lower rate in an AlGaAs crystal than in an AlGaInP crystal, as is known in the art. Therefore, the active layer of the AlGaAs semiconductor laser suffers less degradation due to the diffusion of the atoms than the active layer of the AlGaInP semiconductor layer.

It should be noted that the number of dislocations occurring within the substrate increases with decreasing carrier concentration. Therefore, referring to FIG. 10, an increased number of dislocations are considered to be present in the substrate at carrier concentrations between 1×10¹⁷ cm⁻³ and 2×10¹⁷ cm⁻³. On the other hand, the carrier surface recombination speed is higher in the AlGaAs crystal than in the AlGaInP crystal. Therefore, at low carrier concentrations, the active layer of the AlGaAs semiconductor laser degrades at a higher rate than the active layer of the AlGaInP semiconductor laser.

This is the reason why the operating currents of the AlGaInP semiconductor laser and the AlGaAs semiconductor laser are minimized at different carrier concentrations.

It should be noted that the present embodiment is not limited to the structure shown in FIG. 8. The present embodiment can be applied to a buried ridge type structure in which a current blocking layer of the first conductive type is buried on both sides of the ridge shape of the cladding layer of the second conductive type.

### Fourth Embodiment

A fourth embodiment of the present invention is different from the first to third embodiments in that the fourth embodiment provides a monolithic semiconductor laser which includes an AlGaInP semiconductor laser and an AlGaAs semiconductor laser both formed on an Si—GaAs substrate.

FIG. 11 is a diagram showing the configuration of a semiconductor laser according to the present embodiment.

Referring to the figure, reference numeral 61 denotes an Si—GaAs substrate (that is, a GaAs substrate of a first conductive type). According to the present embodiment, the carrier concentration of the Si—GaAs substrate 61 is set between 1×10¹⁷ cm⁻³ and 7×10¹⁷ cm⁻³, inclusive, as in the case of the first to third embodiments. That is, the carrier concentration is set to less than conventional values. Particularly, the carrier concentration of the substrate is preferably between 3×10¹⁷ cm⁻³ and 5×10¹⁷ cm⁻³, inclusive Further, on the Si—GaAs substrate 61 are formed an AlGaInP semiconductor laser (62), such as that of the first embodiment, and an AlGaAs semiconductor laser (63), such as that of the third embodiment.

The AlGaInP semiconductor laser 62 has a structure in which six layers and a film are grown onto one another in the following order: an Si—GaAs buffer layer 64; an Si—AlGaInP cladding layer 65 (a cladding layer of a first conductive type); an active layer 66 including an AlGaInP/GaInP multiple quantum well (MQW) structure; an Mg—AlGaInP cladding layer 67 (a cladding layer of a second conductive type); an Mg—AlGaInP band discontinuity reduction (hereinafter abbreviated as “BDR”) layer 68; a Zn—GaAs contact layer 69; and an SiN insulating film 70.

The AlGaAs semiconductor laser 63, on the other hand, has a structure in which five layers and a film are grown onto one another in the following order: an Si—GaAs buffer layer 71; an Si—AlGaAs cladding layer 72 (a cladding layer of the first conductive type); an active layer 73 including an AlGaAs/AlGaAs multiple quantum well (MQW) structure; a Zn—AlGaAs cladding layer 74 (a cladding layer of the second conductive type); a Zn—GaAs contact layer 75; and the SiN insulating film 70.

Further, in FIG. 11, reference numeral 77 denotes an n-type electrode, and 78 denotes a p-type electrode.

For example, the following method may be used to manufacture the semiconductor laser of the present embodiment.

First of all, the AlGaAs semiconductor laser 63 is formed on the Si—GaAs substrate 61 in accordance with the method described in connection with the third embodiment.

Then, portions of the upper structure of the AlGaAs semiconductor layer 63 other than a predetermined region are removed (the upper structure including the Si—AlGaAs cladding layer 72 and the layers and film overlying the Si—AlGaAs cladding layer 72). This exposes the surface of the Si—GaAs buffer layer 71.

Then, the structure shown in FIG. 2A described in connection with the first embodiment is formed on the entire top surface. It should be noted that this structure corresponds to the grown structure shown in FIG. 11 made up of the Si—GaAs buffer layer 64, the Si—AlGaInP cladding layer 65, the active layer 66, the Mg—AlGaInP cladding layer 67, the Mg—AlGaInP BDR layer 68, and the Zn—GaAs contact layer 69.

After that, the portions of the grown structure (as shown in FIG. 2A) on the AlGaAs semiconductor laser 63 and on predetermined regions on both sides of the AlGaAs semiconductor laser 63 are removed.

Then, a Zn diffusion window layer (not shown) is formed in the same method as in the first embodiment. After that, a pattern (not shown) is formed by a photolithographic technique; the pattern has openings on both sides of the regions that will become optical waveguides 79 and 80. Then, etching is carried out through these openings until positions each approximately 0.5 μm high from the top surface of the active layer 66 or 73 are reached, thereby forming ridge-shaped optical waveguides 79 and 80.

Then, after forming the SiN insulating film 70 on the entire top surface, the portions of the SiN insulating film 70 (on the Zn—GaAs contact layers) above the optical waveguide portions 79 and 80 are removed, thereby forming the AlGaInP semiconductor laser portion 62.

After that, a p-type electrode 78 is formed on the AlGaAs semiconductor laser 63 and the AlGaInP semiconductor laser 62, and an n-type electrode 77 is formed on the back surface of the Si—GaAs substrate 61. Then, both end faces (of the monolithic semiconductor laser) are formed through cleavage, and an antireflective film (not shown) is formed on these end faces, producing the structure shown in FIG. 11. Referring to FIG. 11, it should be noted that the distance between the light emission points of the AlGaAs semiconductor laser 63 and the AlGaInP semiconductor laser 62 may be set to approximately 110 μm.

It should be further noted that the present embodiment is not limited to the structure shown in FIG. 11. For example, the present embodiment can be applied to a configuration in which at least one of the AlGaInP semiconductor laser and the AlGaAs semiconductor laser has a buried ridge type structure in which a current blocking layer of the first conductive type is buried on both sides of the ridge shape of the cladding layer of the second conductive type.

According to the present embodiment described above, the carrier concentration of the Si—GaAs substrate is set to less than conventional values (for example, it may be set to 7×10¹⁷ cm⁻³ or less), thereby reducing the numbers of Ga and As atoms and Si atoms (acting as impurities) which are present in the interstitial sites of GaAs crystal, as compared to conventional arrangements. This can reduce the number of atoms diffusing from the Si—GaAs substrate to the active layer and thereby allow the active layer of the semiconductor laser to have good light emission characteristics.

It should be noted that the present invention is not limited to the embodiments described above, and various alterations may be made thereto without departing from the spirit and scope of the invention.

For example, the present invention is not limited to the configurations of the AlGaInP semiconductor lasers and the AlGaAs semiconductor laser described in connection with the first to third embodiments. An AlGaInP semiconductor laser or AlGaAs semiconductor laser having a different configuration may be formed on any Si—GaAs substrate having a carrier concentration between 1×10¹⁷ cm⁻³ and 7×10¹⁷ cm⁻³. Such an arrangement can also produce the effect described above.

Further, even though the fourth embodiment was described as applied to a monolithic semiconductor laser that includes an AlGaInP semiconductor laser and an AlGaAs semiconductor laser, the present invention is not limited to this particular arrangement. A monolithic semiconductor laser employing a different type of semiconductor laser may be formed on any Si—GaAs substrate having a carrier concentration between 1×10¹⁷ cm⁻³ and 7×10¹⁷ cm⁻³ with the same effect. Further, the present invention can be applied to a configuration in which a plurality of semiconductor lasers of the same type (such as the AlGaInP semiconductor laser or AlGaAs semiconductor laser) are formed on an Si—GaAs substrate. Such an arrangement can also produce the same effect.

The features and advantages of the present invention may be summarized as follows.

According to the present invention described above, the carrier concentration of the GaAs substrate is set between 1×10¹⁷ cm⁻³ and 7×10¹⁷ cm⁻³, inclusive, to reduce the number of atoms diffusing from the GaAs substrate into the active layer and thereby allow the active layer of the semiconductor laser to have good light emission characteristics.

Obviously many modifications and variations of the present invention are possible in the light of the above teachings. It is therefore to be understood that within the scope of the appended claims the invention may be practiced otherwise than as specifically described.

The entire disclosure of Japanese Patent Applications No. 2004-303750, filed on Oct. 19, 2004 including specification, claims, drawings and summary, on which the Convention priority of the present application is based, are incorporated herein by reference in their entirety.

1. A semiconductor laser comprising:
a GaAs substrate of a first conductivity type; and
a grown structure located over said GaAs substrate, said grown structure including a cladding layer of the first conductivity type, an active layer, and a cladding layer of a second conductivity type, wherein
said cladding layer of the first conductivity type, said active layer, and said cladding layer of the second conductivity type are AlGaInP-based materials, and
said GaAs substrate has a carrier concentration from 1×10¹⁷ cm⁻³ to 7×10¹⁷ cm⁻³, inclusive.

2. The semiconductor laser according to claim 1, wherein said GaAs substrate has a carrier concentration from 3×10¹⁷ cm⁻³ to 5×10¹⁷ cm⁻³, inclusive.

3. The semiconductor laser according to claim 1, wherein said cladding layer of the second conductivity type has a ridge shape.

4. The semiconductor laser according to claim 3, including a current blocking layer of the first conductivity type burying opposite sides of said ridge shape.

5. A semiconductor laser comprising:
a GaAs substrate of a first conductivity type; and
a grown structure located over said GaAs substrate, said grown structure including a cladding layer of the first conductivity type, an active layer, and a cladding layer of a second conductivity type, wherein
said cladding layer of the first conductivity type, said active layer, and said cladding layer of the second conductivity type are AlGaAs-based materials, and
said GaAs substrate has a carrier concentration from 1×10¹⁷ cm⁻³ to 7×10¹⁷ cm⁻³, inclusive.

6. The semiconductor laser according to claim 5, wherein said GaAs substrate has a carrier concentration from 5×10¹⁷ cm⁻³ to 6×10¹⁷ cm⁻³, inclusive.

7. The semiconductor laser according to claim 5, wherein said cladding layer of the second conductivity type has a ridge shape.

8. The semiconductor laser as claimed in claim 7, including a current blocking layer of the first conductivity type burying opposite sides of said ridge shape.

9. A semiconductor laser comprising:
a GaAs substrate of a first conductivity type;
a first grown structure located over said GaAs substrate, said first grown structure including a cladding layer of the first conductivity type, an active layer, and a cladding layer of a second conductivity type, which are AlGaInP-based materials; and
a second grown structure located over said GaAs substrate, said second grown structure including a cladding layer of the first conductivity type, an active layer, and a cladding layer of the second conductivity type, which are AlGaAs-based materials, wherein said GaAs substrate has a carrier concentration from 1×10¹⁷ cm⁻³ to 7×10¹⁷ cm⁻³, inclusive.

10. The semiconductor laser according to claim 9, wherein said GaAs substrate has a carrier concentration from 3×10¹⁷ cm⁻³ to 5×10¹⁷ cm⁻³, inclusive.

11. The semiconductor laser according to claim 9, wherein said cladding layer of the second conductivity type has a ridge shape.

12. The semiconductor laser according to claim 11, including a current blocking layer of the first conductivity type burying opposite sides of said ridge shape.
